(19) United States
(12) Patent Application Publication
(10) Pub. No.: US 2021/0384364 A1
(43) Pub. Date: Dec. 9, 2021

(54) SOLAR CELL STRUCTURE AND FABRICATION METHOD THEREOF

(71) Applicant: TSEC Corporation, New Taipei City (TW)

(72) Inventors: Cheng-Wen Kuo, Kaohsiung City (TW); Yung-Chih Li, Hsinchu County (TW); Ying-Quan Wang, Hsinchu County (TW); Sheng-Kai Wu, Miaoli County (TW); Wen-Ching Chu, New Taipei City (TW); Yu-Hui Liu, Hsinchu County (TW); Ta-Ming Kuan, Hsinchu City (TW); Hung Cheng, Hsinchu County (TW); Jen-Ho Kang, Miaoli County (TW); Cheng-Yeh Yu, Hsinchu City (TW)

(21) Appl. No.: 17/016,361

(22) Filed: Sep. 9, 2020

(30) Foreign Application Priority Data
Jun. 4, 2020 (TW) 109118806

(51) Int. Cl. H01L 31/0216; H01L 31/18; H01L 31/0224

(52) U.S. Cl. CPC H01L 31/02168; H01L 31/022425; H01L 31/1804

(57) ABSTRACT

A solar cell structure includes a semiconductor substrate having a front side and a back side; a pyramid structure disposed on the front side of the semiconductor substrate; a anti-reflection layer disposed on the pyramid structure; a front electrode provided on the anti-reflection layer; a passivation layer provided on the back side of the semiconductor substrate; a dielectric layer disposed on the passivation layer; and a back electrode disposed on the dielectric layer. The reflective layer is a multi-layer anti-reflection layer having at least three coating layers.

### BACKGROUND OF THE INVENTION

### 1. Field of the Invention

The present invention relates to the technical field of solar cells, in particular to an improved crystalline silicon solar cell structure, which can reduce glare at different tilt angles, and is particularly suitable for application in the field of construction.

### 2. Description of the Prior Art

In recent years, under the global promotion of green energy, high expectations have been placed on the power supply of crystalline silicon solar cells, and they have been actively researched, developed and commercialized.

Currently, the crystalline silicon solar cells are mostly used in large-scale power plants, so only the appearance of the battery viewed at eye level is concerned. However, for solar power products used in buildings, the angle of use will be different from those used in general large power plants. For example, when solar cell panels are used in buildings, the glare caused by sunlight reflection must be reduced to avoid negative effects on the surrounding environment or car driving, and so on.

As shown in FIG. 1, if the crystalline silicon solar panels P are installed on the exterior wall of the building B, the sunlight SL generated by the sun S shines on the surface of the solar panels P has different reflectivities at different inclination angles Θ relative to the human eye HE. For example, when the tilt angle Θ=80 degrees, the reflectivity is about 11.66%, and when the tilt angle Θ=60 degrees, the reflectivity is about 13.60%, which produce glare and discomfort to the human eye.

It can be seen that when the crystalline silicon solar cell is applied to the exterior wall of a building, the glare caused by the above-mentioned reflection at different inclination angles still needs to be overcome. Therefore, there is still a need for an improved solar cell in this technical field, which has a design to reduce glare at different tilt angles.

### SUMMARY OF THE INVENTION

One object of the present invention is to provide an improved crystalline silicon solar cell structure and a manufacturing method thereof, which can reduce glare at different tilt angles, so that the crystalline silicon solar cell can be applied in the construction field.

One aspect of the invention provides a solar cell structure including a semiconductor substrate having a front side and a back side; a pyramid structure disposed on the front side of the semiconductor substrate; a anti-reflection layer disposed on the pyramid structures; a front electrode provided on the anti-reflection layer; a passivation layer provided on the back side of the semiconductor substrate; a dielectric layer disposed on the passivation layer; and a back electrode disposed on the dielectric layer. The reflective layer is a multi-layer anti-reflection layer having at least three coating layer.

According to some embodiments, the semiconductor substrate comprises an N-type or P-type doped crystalline silicon substrate, or a crystalline silicon wafer.

According to some embodiments, the anti-reflection layer comprises silicon nitride, silicon oxynitride, tungsten oxide, or titanium dioxide.

According to some embodiments, the anti-reflection layer includes 3-10 coating layers.

According to some embodiments, the anti-reflection layer has a thickness between 40 nm and 120 nm.

According to some embodiments, the dielectric layer comprises silicon nitride, silicon oxynitride, tungsten oxide, or titanium dioxide.

According to some embodiments, the dielectric layer has a thickness between 10 nm and 300 nm.

According to some embodiments, the solar cell structure further includes a doped area on the front side of the semiconductor substrate.

According to some embodiments, the passivation layer comprises silicon dioxide, aluminum oxide, silicon nitride, silicon oxynitride, or titanium dioxide.

According to some embodiments, the pyramid structure has a height of about 1 to 5 μm.

According to some embodiments, the solar cell structure has an average reflectivity under different tilt angles less than 7%.

Another aspect of the invention provides a method for fabricating a solar cell structure. A semiconductor substrate having a front side and a back side is provided. A pyramid structure is formed on the front side of the semiconductor substrate. A anti-reflection layer is formed on the pyramid structure. The reflective layer is a multi-layer anti-reflection layer having at least three coating layers. A front electrode is formed on the anti-reflection layer. A passivation layer is formed on the back side of the semiconductor substrate. A dielectric layer is formed on the passivation layer. A back electrode is formed on the dielectric layer.

According to some embodiments, the semiconductor substrate comprises an N-type or P-type doped crystalline silicon substrate, or a crystalline silicon wafer.

According to some embodiments, the anti-reflection layer comprises silicon nitride, silicon oxynitride, tungsten oxide, or titanium dioxide.

According to some embodiments, the anti-reflection layer includes 3-10 coating layers.

According to some embodiments, the anti-reflection layer has a thickness between 40 nm and 120 nm.

According to some embodiments, the dielectric layer comprises silicon nitride, silicon oxynitride, tungsten oxide, or titanium dioxide.

According to some embodiments, the dielectric layer has a thickness between 10 nm and 300 nm.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates that the crystalline silicon solar panels are installed on the external wall of the building, wherein the sunlight illuminates the surface of the solar cell panel, which has different reflectivity at different tilt angles relative to the human eye.

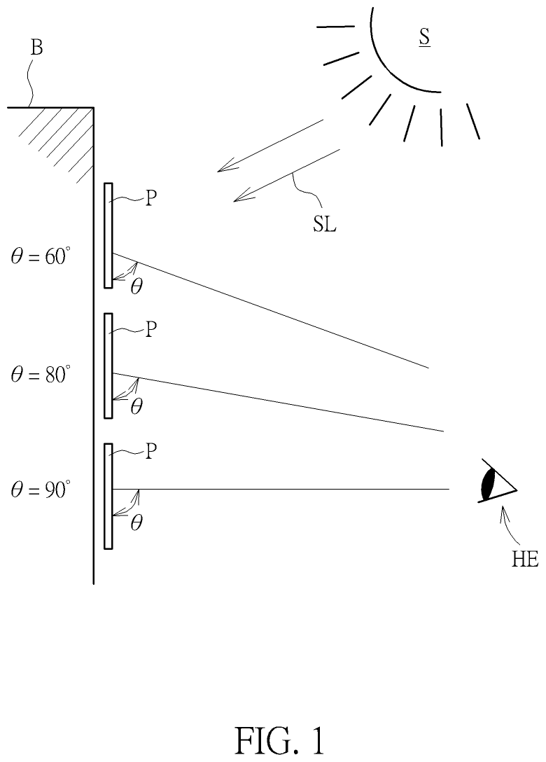

FIG. 2 is a schematic cross-sectional view of a solar cell structure according to an embodiment.

FIG. 3 illustrates a flow chart for manufacturing the solar cell structure.

FIG. 4 illustrates the structure of a finished solar cell in a cross-sectional view.

FIG. 5 shows the drop in reflectivity of the traditional solar cell and the reflectivity of the solar cell of the present invention under different tilt angles.

FIG. 6 is a plot of the reflectance drop versus tilt angle in FIG. 5.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized and structural, logical, and electrical changes may be made without departing from the scope of the present invention. Therefore, the following detailed description is not to be considered as limiting, but the embodiments included herein are defined by the scope of the accompanying claims.

Solar cell is a photoelectric element that combines P-type and N-type semiconductor materials to form the positive and negative electrodes. When the solar cell is irradiated by sunlight, it will absorb sunlight energy to generate electrons and holes. The positive charges (holes) and the negative charges (electrons) will move to the positive (P-type) and negative (N-type) directions respectively, generating a direct current. This type of photovoltaic element can convert light energy into electrical energy, so it is also called photovoltaic (PV).

Generally, the method for manufacturing a solar cell includes cleaning and roughening the surface of the wafer first, and then performing a diffusion process to form a phosphor glass layer and a doped emitter area on the wafer surface, and then removing the phosphor glass layer by an etching process. The anti-reflection layer is then removed. By using the screen printing technology, the electrode pattern is printed with metal paste on the front and back of the battery. By performing high-temperature sintering, the electrode is formed. Finally, the batteries (such as 6×10 or 6×12 arrays) are arranged and positioned on the glass substrate, and then stringer is performed, and the battery cells are connected in series to form solar modules through copper ribbon.

Since the current anti-reflection layer design of general solar cells has reached an optimized design, arbitrary changes may cause the photoelectric conversion efficiency of the solar cells to decline. The present invention therefore proposes an improved crystalline silicon solar cell structure and a manufacturing method thereof, which can reduce oblique angle glare without reducing the photoelectric conversion efficiency of the solar cell, so that the crystalline silicon solar cell is suitable for application in the construction field.

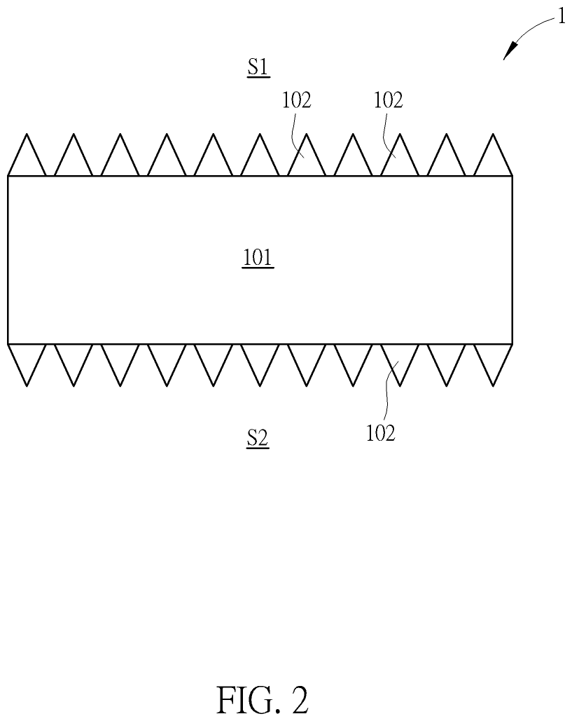

Please refer to FIG. 2, which is a schematic cross-sectional view of a solar cell structure according to an embodiment. As shown in FIG. 2, the solar cell structure 1 includes a semiconductor substrate 101, such as an N-type or P-type doped crystalline silicon substrate or a crystalline silicon wafer, the thickness of which is, for example, about 60 to 200 microns (μm), but is not limited to this. On the front side (light-receiving side) S1 and the back side S2 of the semiconductor substrate 10, a surface roughening process is used to form a pyramid structure 102 with a height of about 1 to 5 μm.

Generally, before (or after) forming the pyramid structure 102, a wafer surface cleaning process may be performed to remove contaminants or cutting damage. Generally, the pyramid structure 102 can be formed using potassium hydroxide (KOH), but it is not limited thereto.

According to an embodiment, after the pyramid structure 102 is formed, a cleaning process can be continued.

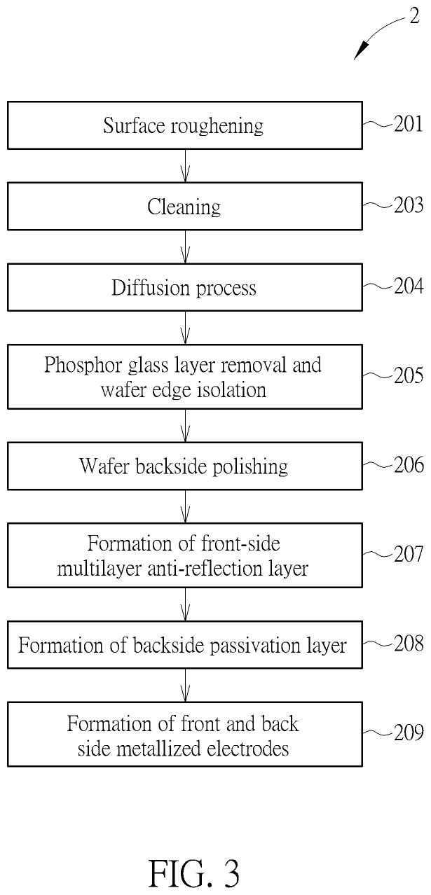

FIG. 3 illustrates a flow chart for manufacturing a solar cell structure. As shown in FIG. 3, the process 2 includes: after the surface roughening (Step 201) is completed, then the wafer surface is cleaned (Step 203), then the diffusion process (Step 204) is performed, and then the phosphor glass layer is removed and wafer edge isolation is performed (Step 205), then the backside of the wafer is polished (Step 206), and an anti-reflection layer is formed on the front side of the wafer (Step 207), a passivation layer is then formed on the backside of the wafer (Step 208), and then metallized electrodes are formed on the front and back sides of the wafer (Step 209).

According to an embodiment, after the backside polishing of the wafer (Step 206), the wafer can be sent to a high-temperature furnace to grow a SiO₂ layer having a thickness of below 2 nm on the surface of the wafer at about 700˜800° C., or use chemical solvent to perform surface cleaning and grow SiO₂ layer having a thickness of below 2 nm on the wafer surface, or use atomic layer deposition (ALD) or chemical phase deposition (CVD) to form Al₂O₃, SiₓN_{y}, SiO₂, SiON, TiO₂ or other oxide layers having a thickness of below 2 nm on the wafer surface.

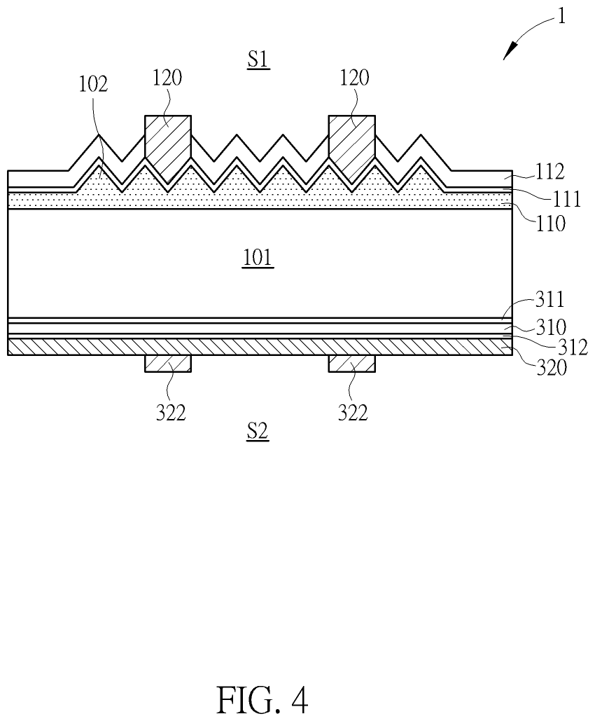

FIG. 4 illustrates the structure of a finished solar cell in a cross-sectional view. As shown in FIG. 4, the solar cell structure 1 has a pyramid structure 102 on its front side S1. The pyramid structure 102 may be formed using potassium hydroxide, but is not limited thereto.

According to an embodiment, the solar cell structure 1 has a doped region 110 formed on its front side S1. The doped area 110 can be formed by using a diffusion furnace to provide phosphorous chloride oxide (POCl₃) gas diffusion, and then using hydrofluoric acid (HF) and other wet etching methods to remove the phosphorus glass (PSG) (not shown) from the surface of the semiconductor substrate.

According to an embodiment, the solar cell structure 1 is further formed with an anti-reflection layer 112 on the front side S1 of the solar cell structure 1, such as silicon nitride, silicon oxynitride, tungsten oxide, or titanium dioxide, but not limited thereto. The thickness of the anti-reflective layer 112 may be between 40 nm and 120 nm. According to an embodiment, the anti-reflection layer 112 is a multilayer structure including at least three coating layers, for example, 3-10 layers, including, for example, silicon nitride, silicon oxynitride, tungsten oxide, or titanium dioxide, but is not limited thereto. According to an embodiment, the multilayer anti-reflection layer 112 may be formed by plasma enhanced chemical vapor deposition (PECVD) or low pressure chemical vapor deposition (LPCVD), but is not limited thereto.

According to an embodiment, the solar cell structure 1 further has a front metal electrode (or front electrode) 120 formed on the front side S1 of the solar cell structure 1, which can penetrate the anti-reflective layer 112 by sintering, and is electrically connected to the doped region 110 below. The front metal electrode 120 can be formed by screen printing or the like.

According to an embodiment, the solar cell structure 1 has a passivation layer 310 formed on the back side S2. For example, the passivation layer 310 may comprise silicon dioxide, aluminum oxide, silicon nitride, silicon oxynitride, titanium dioxide, or the like. For example, if the passivation layer 310 is silicon dioxide, it can be formed using a high temperature furnace tube at a high temperature of 700 to 800 degrees Celsius, or it can be cleaned and grown using a chemical solvent, or it can be formed using atomic layer deposition or chemical vapor deposition.

According to an embodiment, the solar cell structure 1 may optionally have an dielectric layer 312 formed on its back side S2, such as silicon nitride, silicon oxynitride, tungsten oxide, or titanium dioxide, but it is not limited thereto. The thickness of the dielectric layer 312 may be between 10 nm and 300 nm.

According to an embodiment, the solar cell structure 1 further has a back metal electrode (or back electrode) 320 and a pad 322 formed on the back side S2. According to an embodiment, the back metal electrode 320 is formed on the dielectric layer 312. The back metal electrode 320 can be formed by screen printing or the like. It should be noted that the above-mentioned process steps, sequences, and structures are only examples, and the technical means and methods used are only examples, and the film materials and process parameters are not limited to the above description.

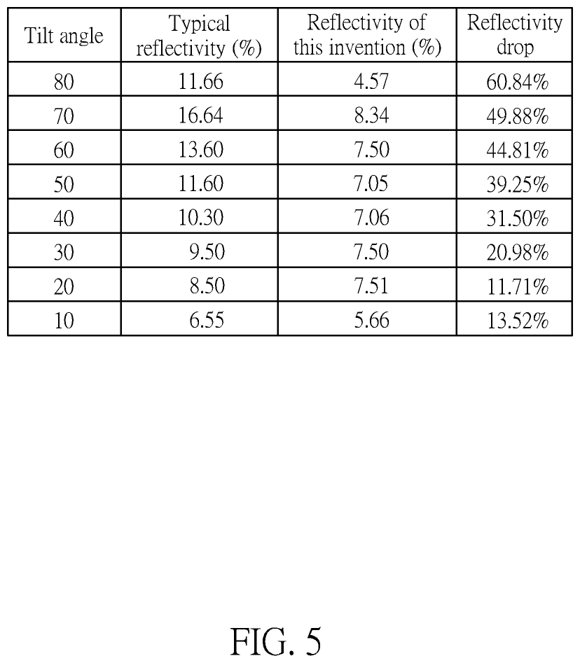

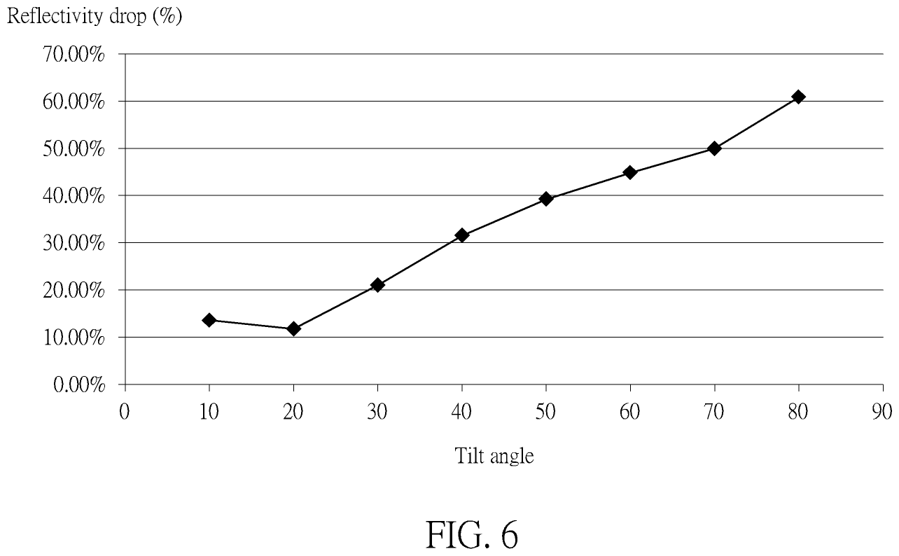

The invention utilizes a multi-layer (3-10 layers) anti-reflection layer formed on the front side of the solar cell structure, which can reduce the visual difference in appearance under different tilt angles and reduce glare, so that the crystalline silicon solar cell can be applied in the construction field. From the measurement results in FIG. 5 and FIG. 6, it can be seen that when the tilt angle Θ=80 degrees, the reflectivity drop can reach 60.84%, and when the tilt angle Θ=60 degrees, the reflectivity drop can also reach 44.81%, and the average reflectivity under different tilt angles can be less than 7%, which shows that the solar cell of the present invention can indeed reduce glare, and the effect is significant.

Those skilled in the art will readily observe that numerous modifications and alterations of the device and method may be made while retaining the teachings of the invention. Accordingly, the above disclosure should be construed as limited only by the metes and bounds of the appended claims.

1. A solar cell structure, comprising:
a semiconductor substrate having a front side and a back side;
a pyramid structure disposed on the front side of the semiconductor substrate;
a anti-reflection layer disposed on the pyramid structure, wherein the reflective layer is a multi-layer anti-reflection layer having at least three coating layers;
a front electrode provided on the anti-reflection layer;
a passivation layer provided on the back side of the semiconductor substrate;
a dielectric layer disposed on the passivation layer; and
a back electrode disposed on the dielectric layer.

2. The solar cell structure according to claim 1, wherein the semiconductor substrate comprises an N-type or P-type doped crystalline silicon substrate, or a crystalline silicon wafer.

3. The solar cell structure according to claim 1, wherein the anti-reflection layer comprises silicon nitride, silicon oxynitride, tungsten oxide, or titanium dioxide.

4. The solar cell structure according to claim 1, wherein the anti-reflection layer includes 3-10 coating layers.

5. The solar cell structure according to claim 1, wherein the anti-reflection layer has a thickness between 40 nm and 120 nm.

6. The solar cell structure according to claim 1, wherein the dielectric layer comprises silicon nitride, silicon oxynitride, tungsten oxide, or titanium dioxide.

7. The solar cell structure according to claim 1, wherein the dielectric layer has a thickness between 10 nm and 300 nm.

8. The solar cell structure according to claim 1 further comprising a doped area on the front side of the semiconductor substrate.

9. The solar cell structure according to claim 1, wherein the passivation layer comprises silicon dioxide, aluminum oxide, silicon nitride, silicon oxynitride, or titanium dioxide.

10. The solar cell structure according to claim 1, wherein the pyramid structure has a height of about 1 to 5 μm.

11. The solar cell structure according to claim 1, wherein the solar cell structure has an average reflectivity under different tilt angles less than 7%.

12-18. (canceled)
